(19) United States
(12) Patent Application Publication
(10) Pub. No.: US 2012/0241935 A1
(43) Pub. Date: Sep. 27, 2012

(54) PACKAGE-ON-PACKAGE STRUCTURE

(75) Inventors: Shih-Wen Chou, Hsinchu (TW); Yu-Tang Pan, Hsinchu (TW)

(73) Assignee: CHIPMOS TECHNOLOGIES INC., Hsinchu (TW)

(21) Appl. No.: 13/205,649

(22) Filed: Aug. 9, 2011

(30) Foreign Application Priority Data
Mar. 24, 2011 (TW) 100110160

(51) Int. Cl. H01L 23/34

(52) U.S. Cl. 257/686; 257/E23.08

(57) ABSTRACT

A package-on-package structure includes first and second package structures and bumps. The first package structure includes a carrier, a chip configured on the carrier, a heat spreader, and an encapsulant. The chip is electrically connected to the carrier through conductive wires. The heat spreader includes a support portion located on the chip and connection portions located respectively at two opposite sides of the support portion. The heat spreader has a circuit layer thereon, covers the chip and the conductive wires, and electrically connects the carrier through the circuit layer on the connecting portions. The encapsulant encapsulates the chip, the conductive wires, a portion of the heat spreader, and a portion of the carrier. The bumps are configured on the support portion. The second package structure is configured on the first package structure and is electrically connected to the first package structure through the bumps.

### CROSS-REFERENCE TO RELATED APPLICATION

This application claims the priority benefit of Taiwan application serial no. 100110160, filed Mar. 24, 2011. The entirety of the above-mentioned patent application is hereby incorporated by reference herein and made a part of this specification.

### BACKGROUND OF THE INVENTION

1. Field of the Invention

The invention relates to a package-on-package (POP) structure. More particularly, the invention relates to a POP structure that is characterized by favorable heat-dissipating efficacy and equipped with a re-layout circuit.

2. Description of Related Art

With rapid advance in science and technologies, integrated circuit (IC) devices have been extensively applied in out daily lives. In general, IC production can be roughly classified into three main stages: a silicon wafer fabrication stage, an IC fabrication stage, and an IC package stage. Among the existing package structures, a package-on-package (POP) structure is one of the well-known package structures.

As indicated in FIG. 4, a conventional POP structure is often constituted by stacked chip package structures 40 and 42. The chip package structure 40 includes a carrier 400, a chip 402, a spacer 404, a re-layout board 406, and an encapsulant 414. The chip 402 is fixed to the carrier 400 through an adhesion layer 408. The spacer 404 and the re-layout board 406 are sequentially configured on the chip 402. The chip 402 is electrically connected to the carrier 400 through conductive wires 410. The re-layout board 406 is electrically connected to the carrier 400 through conductive wires 412. The encapsulant 414 encapsulates a portion of the carrier 400, the chip 402, the spacer 404, the conductive wires 410 and 412, and a portion of the re-layout board 406. The chip package structure 42 includes a carrier 416, a chip 418, and an encapsulant 420. The chip 418 is fixed to the carrier 416 through an adhesion layer 422 and is electrically connected to the carrier 416 through conductive wires 424. The encapsulant 420 encapsulates a portion of the carrier 416, the chip 418, and the conductive wires 424. Besides, the chip package structure 42 is stacked onto the chip package structure 40 and electrically connected to the re-layout board 406 of the chip package structure 40 through bumps 426. Thereby, the chip package structure 42 can be electrically connected to the carrier 400 through the bumps 426, the re-layout board 406, and the conductive wires 412. The chip package structure 40 further includes bumps 428 through which the chip package structure 40 can be electrically connected to other external devices.

However, in the above-mentioned POP structure, the re-layout board 406 is configured on the chip 402 and the spacer 404, and thus the length of the conductive wires 412 must be sufficient, which is likely to cause collapse of the conductive wires 412. Additionally, the POP structure may encounter the issue of poor heat-dissipating efficiency.

From another perspective, the re-layout board 406 is configured on the chip 402 through the spacer 404, such that the re-layout board 406 and the chip package structure 42 can be horizontally held. Consequently, a relatively large number of components are required in the conventional POP structure. Moreover, when the encapsulant 420 is formed, the flowing molding compound easily causes the re-layout board 406 to incline, and accordingly the reliability of the entire product is negatively affected.

### SUMMARY OF THE INVENTION

In view of the above, the invention is directed to a POP structure that is characterized by favorable heat-dissipating efficacy and equipped with a re-layout circuit.

In an embodiment of the invention, a POP structure that includes a first package structure, a plurality of bumps, and a second package structure is provided. The first package structure includes a first carrier, a first chip, a heat spreader, and a first encapsulant. The first chip is configured on the first carrier and electrically connected to the first carrier through a plurality of first conductive wires. The heat spreader includes a support portion and a plurality of connection portions. The heat spreader has a circuit layer thereon. The support portion is located above the first chip. The connection portions are located respectively at two opposite sides of the support portion. Besides, the head spreader covers the first chip and the first conductive wires and is electrically connected to the first carrier through the circuit layer on the connecting portions. The first encapsulant encapsulates the first chip, the first conductive wires, a portion of the heat spreader, and a portion of the first carrier. The bumps are configured on the support portion. The second package structure is configured on the first package structure and is electrically connected to the first package structure through the bumps.

According to an embodiment of the invention, the heat spreader has an upper surface and a lower surface opposite to the upper surface, for instance. The circuit layer is configured on the upper surface. The bumps are electrically connected to the circuit layer. The first package structure can further include a plurality of second conductive wires, and the circuit layer located on the connection portions is electrically connected to the first carrier through the second conductive wires.

In an embodiment of the invention, a POP structure that includes a first package structure, a plurality of bumps, and a second package structure is provided. The first package structure includes a first carrier, a first chip, a heat spreader, and a first encapsulant. The first chip is configured on the first carrier and electrically connected to the first carrier through a plurality of first conductive wires. The heat spreader includes a support portion and a plurality of connection portions. The heat spreader has an upper surface and a lower surface opposite to the upper surface, and a circuit layer is configured on the lower surface. The support portion is located above the first chip. The connection portions are located respectively at two opposite sides of the support portion. Besides, the head spreader covers the first chip and the first conductive wires. The heat spreader has a plurality of conductive vias, and the heat spreader is electrically connected to the first carrier through the circuit layer located on the connection portions. The first encapsulant encapsulates the first chip, the first conductive wires, a portion of the heat spreader, and a portion of the first carrier. The bumps are configured on the support portion and electrically connected to the circuit layer through the conductive vias. The second package structure is configured on the first package structure and is electrically connected to the first package structure through the bumps.

According to an embodiment of the invention, an insulation layer is configured between outer edges of the conductive vias and the heat spreader, for instance.

According to an embodiment of the invention, the POP structure can further include an adhesion layer that is configured between the connection portions and the first carrier.

According to an embodiment of the invention, the adhesion layer is, for instance, a conductive material selected from solder tin, silver paste, and an anisotropic conductive film (ACF).

According to an embodiment of the invention, the adhesion layer is, for instance, an insulation material selected from epoxy resin, a B-stage adhesive, a non-conductive paste (NCP), and a non-conductive film (NCF).

According to an embodiment of the invention, the heat spreader includes a metal core layer and an insulation layer, for instance. The insulation layer is configured on a surface of the metal core layer, and the circuit layer is configured on the insulation layer.

According to an embodiment of the invention, the second package structure includes a second carrier, a second chip, and a second encapsulant. The second carrier is electrically connected to the first package structure through the bumps. The second chip is configured on the second carrier and electrically connected to the second carrier through a plurality of second conductive wires. The second encapsulant encapsulates the second chip, the second conductive wires, and a portion of the second carrier.

According to an embodiment of the invention, the first carrier has a front surface, a back surface, and a through hole, for instance. The first chip is configured on the front surface of the first carrier. The first conductive wires pass through the through hole and are electrically connected to the back surface of the first carrier.

As described in the embodiments of the invention, the heat spreader has the circuit layer and is electrically connected to the carrier through the circuit layer. Besides, the heat spreader is electrically insulated from the chip. Accordingly, the heat spreader can replace the spacer and the re-layout board disclosed in the related art and can still hold the overlying package structure and dissipate heat. As such, the POP structure described in the embodiments of the invention can have favorable heat-dissipating efficacy.

In order to make the aforementioned and other features and advantages of the invention more comprehensible, several embodiments accompanied with figures are described in detail below.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic cross-sectional view illustrating a POP structure according to a first embodiment of the invention.

FIG. 2 is a schematic cross-sectional view illustrating a POP structure according to a second embodiment of the invention.

FIG. 3 is a schematic cross-sectional view illustrating a POP structure according to a third embodiment of the invention.

FIG. 4 is a schematic cross-sectional view illustrating a conventional POP structure.

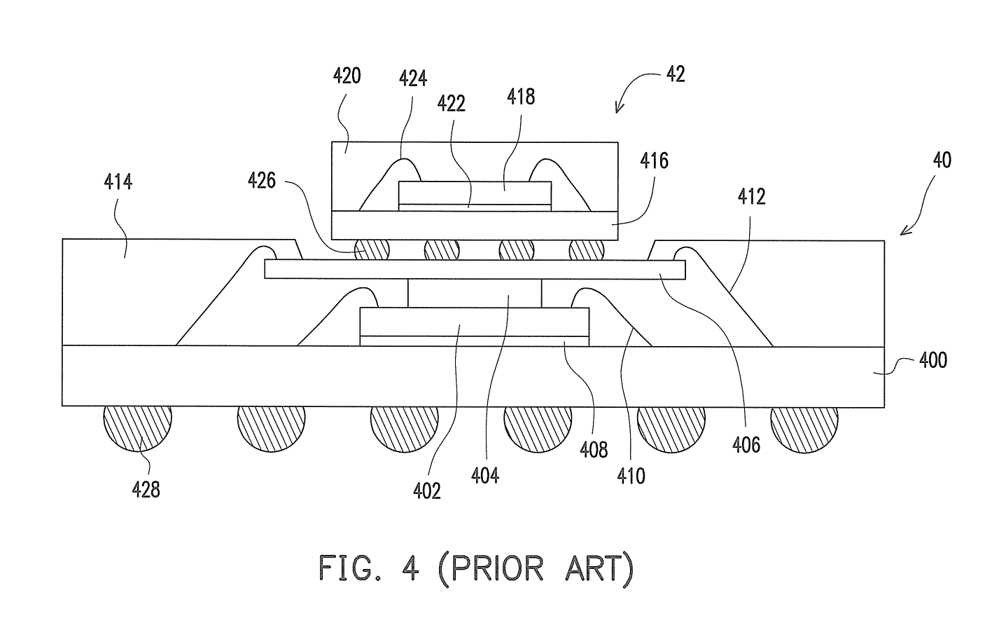

### DESCRIPTION OF EMBODIMENTS

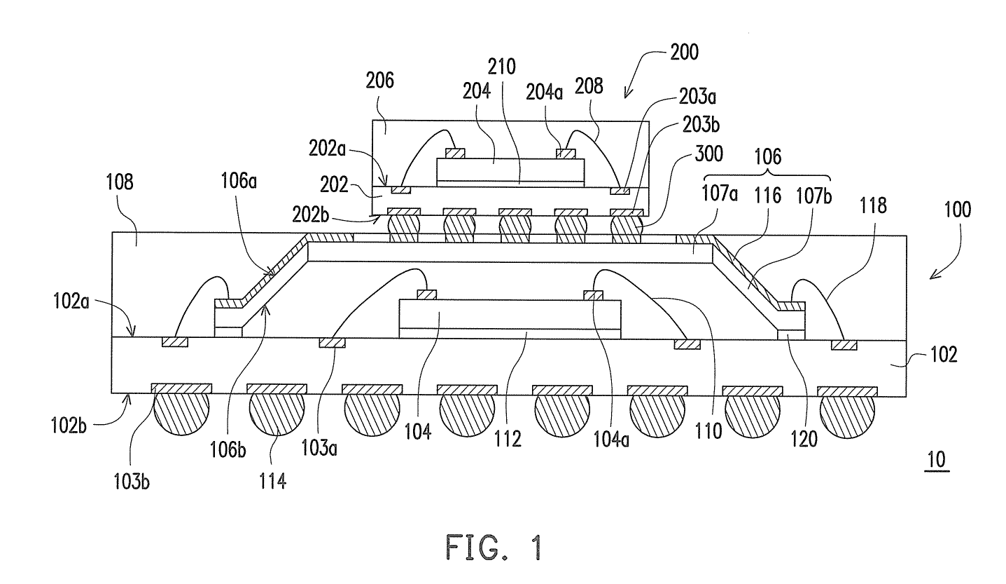

FIG. 1 is a schematic cross-sectional view illustrating a POP structure according to a first embodiment of the invention. With reference to FIG. 1, the POP structure 10 includes a first package structure 100, a second package structure 200, and a plurality of bumps 300. The first package structure 100 includes a carrier 102, a chip 104, a heat spreader 106, and an encapsulant 108. The second package structure 200 includes a carrier 202, a chip 204, and an encapsulant 206.

In the first package structure 100, the chip 104 is configured on a front surface 102a of the carrier 102. The carrier 102 is a circuit board, for instance. The chip 104 has bonding pads 104a, and the carrier 102 has bonding pads 103a. The bonding pads 104a of the chip 104 are electrically connected to the bonding pads 103a of the carrier 102 through conductive wires 110. In this embodiment, an adhesion layer 112 is configured between the chip 104 and the carrier 102, so as to fix the chip 104 onto the carrier 102. A plurality of bonding pads 103b are located on a back surface 102b of the carrier 102. A plurality of bumps 114 and the bonding pads 103b are electrically connected, such that the POP structure 10 can be electrically connected to other external devices through the bumps 114.

The heat spreader 106 includes a support portion 107a and a plurality of connection portions 107b. The support portion 107a is located above the chip 104. The connection portions 107b are respectively located at two opposite sides of the support portion 107a. The chip 104 and the conductive wires 110 are located between the connection portions 107b, such that the heat spreader 106 covers the chip 104 and the conductive wires 110, and that the heat spreader 106 is electrically insulated from the chip 104 and the conductive wires 110. In this embodiment, the heat spreader 106 has an upper surface 106a and a lower surface 106b opposite to the upper surface 106a. Besides, the heat spreader 106 has a circuit layer 116 located on the upper surface 106a, and the circuit layer 116 located on the connection portions 107b is electrically connected to the bonding pads 103a of the carrier 102 through the conductive wires 118. In an embodiment of the invention, the heat spreader 106 is constituted by a metal core layer and an insulation layer located on a surface of the metal core layer, for instance, and the circuit layer 116 is configured on the insulation layer.

Besides, the adhesion layer 120 is configured between the connection portions 107b and the carrier 102. According to an embodiment of the invention, the adhesion layer 120 is an insulation material selected from epoxy resin, a B-stage adhesive, an NCP, and an NCF. In another embodiment of the invention, the adhesion layer 120 can be a conductive material selected from solder tin, silver paste, and an ACF.

The encapsulant 108 encapsulates the chip 104, the conductive wires 110, a portion of the carrier 102, and a portion of the heat spreader 106. Besides, the encapsulant 108 exposes a top surface of the support portion 107a of the heat spreader 106.

Similar to the first package structure 100, the second package structure 200 has the chip 204 that is configured on a front surface 202a of the carrier 202. The carrier 202 is a circuit board, for instance. The chip 204 has bonding pads 204a, and the carrier 202 has bonding pads 203a. The bonding pads 204a of the chip 204 are electrically connected to the bonding pads 203a of the carrier 202 through conductive wires 208. In this embodiment, an adhesion layer 210 is configured between the chip 204 and the carrier 202, so as to fix the chip 204 onto the carrier 202. A plurality of bonding pads 203b are located on a back surface 202b of the carrier 202. The encapsulant 206 encapsulates the chip 204, the conductive wires 208, and a portion of the carrier 202.

The bumps 300 are configured on the support portion 107a of the heat spreader 106 in the first package structure 100. The second package structure 200 is configured above the first package structure 100. Besides, the bonding pads 203b are electrically connected to the circuit layer 116 on the support portion 107a through the bumps 300.

In this embodiment, the heat spreader 106 has the circuit layer 116 thereon, and the second package structure 200 is electrically connected to the carrier 102 through the circuit layer 116. Therefore, the heat spreader 106 can replace the spacer and the re-layout board disclosed in the related art and can still hold the second package structure 200 and dissipate heat. Additionally, the re-layout circuit (i.e., the circuit layer 116) can extend from the connection portions 107b of the heat spreader 106, which apparently reduces the length of wires and prevents excessively long wires from being collapsed or deviated during the package process. Thereby, the POP structure 10 can have favorable heat-dissipating efficacy. Moreover, the POP structure 10 can have the re-layout circuit and can firmly hold the second package structure 200. The length of wires in the POP structure 10 can be reduced as well.

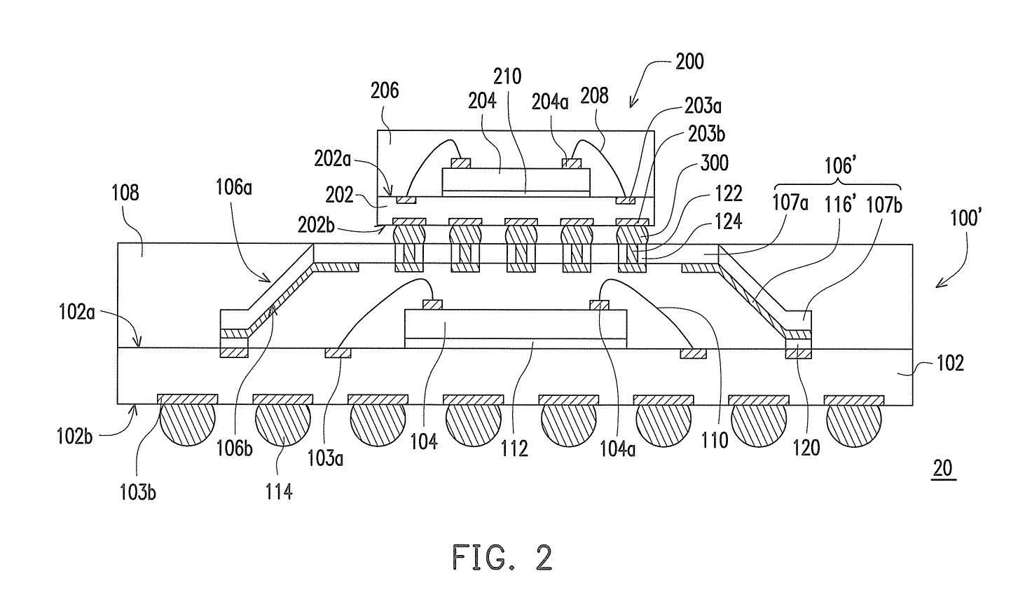

FIG. 2 is a schematic cross-sectional view illustrating a POP structure according to a second embodiment of the invention. Similar elements in FIG. 1 and FIG. 2 are marked by similar numbers. With reference to FIG. 2, the difference between the POP structure 20 and the POP structure 10 lies in the structure of the heat spreader. To be more specific, in the first package structure 100′, the heat spreader 106′ has a circuit layer 116′ located on the lower surface 106b, and the heat spreader 106′ has a plurality of conductive vias 122. The conductive vias 122 are made of conductive metal materials, such as gold, silver, copper, aluminum, and so on, for instance. Besides, the conductive vias 122 are electrically connected to the circuit layer 116′. An insulation layer 124 is configured between outer edges of the conductive vias 122 and the heat spreader 106′. The bumps 300 are electrically connected to the circuit layer 116′ through the conductive vias 122 and electrically connected to the carrier 102 through the circuit layer 116′ that is located on the connection portions 107b. Preferably, an adhesion layer 120 can be configured between the connection portions 107b and the carrier 102. The adhesion layer 120 can be a conductive material selected from solder tin, silver paste, and an ACF. Therefore, the conductive wires 118 are no longer required for electrically connecting the carrier 102.

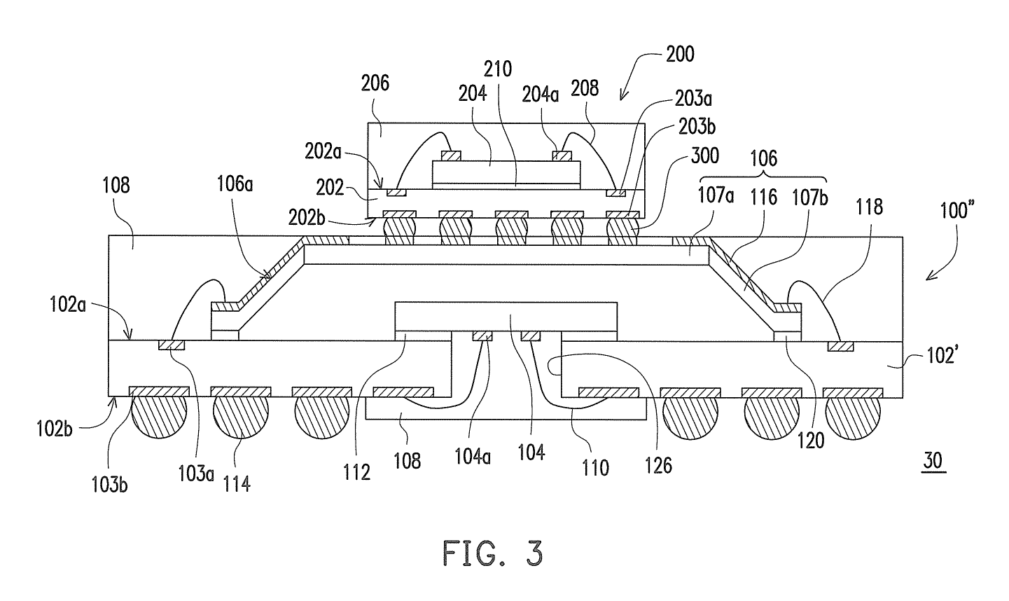

FIG. 3 is a schematic cross-sectional view illustrating a POP structure according to a third embodiment of the invention. Similar elements in FIG. 1 and FIG. 3 are marked by similar numbers. With reference to FIG. 3, the difference between the POP structure 30 and the POP structure 10 lies in the structure of the carrier and the arrangement of the chip. Particularly, in the first package structure 100″, the carrier 102′ has a through hole 126. The chip 104 is configured on the front surface 102a of the carrier 102′. The through hole 126 exposes the bonding pads 104a. The conductive wires 110 pass through the through hole 126 and are electrically connected to the bonding pads 103b of the carrier 102′.

Since the heat spreader 106′, the connection between the heat spreader 106′ and the second package structure 200, and the connection between the heat spreader 106′ and the carrier 102 depicted in FIG. 2 are applicable to the POP structure shown in FIG. 3, no further description is provided herein.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A package-on-package structure comprising:
a first package structure comprising:
a first carrier;
a first chip configured on the first carrier and electrically connected to the first carrier through a plurality of first conductive wires;
a heat spreader comprising a support portion and a plurality of connection portions, the heat spreader having a circuit layer thereon, wherein the support portion is located above the first chip, and the connection portions are respectively located at two opposite sides of the support portion, the heat spreader covering the first chip and the first conductive wires and being electrically connected to the first carrier through the circuit layer located on the connection portions; and
a first encapsulant encapsulating the first chip, the first conductive wires, a portion of the heat spreader, and a portion of the first carrier;
a plurality of bumps configured on the support portion; and
a second package structure configured on the first package structure and electrically connected to the first package structure through the bumps.

2. The package-on-package structure as recited in claim 1, the heat spreader having an upper surface and a lower surface opposite to the upper surface, the circuit layer being configured on the upper surface, the bumps being electrically connected to the circuit layer, the first package structure further comprising a plurality of second conductive wires, the circuit layer located on the connection portions being electrically connected to the first carrier through the second conductive wires.

3. The package-on-package structure as recited in claim 2, further comprising an adhesion layer configured between the connection portions and the first carrier.

4. The package-on-package structure as recited in claim 3, wherein the adhesion layer is an insulation material selected from epoxy resin, a B-stage adhesive, a non-conductive paste, and a non-conductive film.

5. The package-on-package structure as recited in claim 1, wherein the heat spreader comprises a metal core layer and an insulation layer, the insulation layer is configured on a surface of the metal core layer, and the circuit layer is configured on the insulation layer.

6. The package-on-package structure as recited in claim 1, the second package structure comprising:
a second carrier electrically connected to the first package structure through the bumps;
a second chip configured on the second carrier and electrically connected to the second carrier through a plurality of second conductive wires; and
a second encapsulant encapsulating the second chip, the second conductive wires, and a portion of the second carrier.

7. The package-on-package structure as recited in claim 1, wherein the first carrier has a front surface, a back surface, and a through hole, the first chip is configured on the front surface of the first carrier, and the first conductive wires pass through the through hole and are electrically connected to the back surface of the first carrier.

8. A package-on-package structure comprising:
a first package structure comprising:
a first carrier;
a first chip configured on the first carrier and electrically connected to the first carrier through a plurality of first conductive wires;
a heat spreader comprising a support portion and a plurality of connection portions, the heat spreader has an upper surface and a lower surface opposite to the upper surface, a circuit layer is configured on the lower surface, wherein the support portion is located above the first chip, and the connection portions are respectively located at two opposite sides of the support portion, the heat spreader covering the first chip and the first conductive wires, the heat spreader has a plurality of conductive vias, and the heat spreader is electrically connected to the first carrier through the circuit layer located on the connection portions; and
a first encapsulant encapsulating the first chip, the first conductive wires, a portion of the heat spreader, and a portion of the first carrier;
a plurality of bumps configured on the support portion and electrically connected to the circuit layer through the conductive vias; and
a second package structure configured on the first package structure and electrically connected to the first package structure through the bumps.

9. The package-on-package structure as recited in claim 8, wherein an insulation layer is configured between outer edges of the conductive vias and the heat spreader.

10. The package-on-package structure as recited in claim 8, further comprising an adhesion layer configured between the connection portions and the first carrier.

11. The package-on-package structure as recited in claim 10, wherein the adhesion layer is a conductive material selected from solder tin, silver paste, and an anisotropic conductive film.

12. The package-on-package structure as recited in claim 8, wherein the heat spreader comprises a metal core layer and an insulation layer, the insulation layer is configured on a surface of the metal core layer, and the circuit layer is configured on the insulation layer.

13. The package-on-package structure as recited in claim 8, the second package structure comprising:
a second carrier electrically connected to the first package structure through the bumps;
a second chip configured on the second carrier and electrically connected to the second carrier through a plurality of second conductive wires; and
a second encapsulant encapsulating the second chip, the second conductive wires, and a portion of the second carrier.

14. The package-on-package structure as recited in claim 8, wherein the first carrier has a front surface, a back surface, and a through hole, the first chip is configured on the front surface of the first carrier, and the first conductive wires pass through the through hole and are electrically connected to the back surface of the first carrier.
